(19) United States
(12) Patent Application Publication
(10) Pub. No.: US 2010/0313943 A1
(43) Pub. Date: Dec. 16, 2010

(54) Thin-film solar cell and process for producing it

(76) Inventors: Hartmut Knoll, Bitterfeld (DE); Markus Renno, Jena (DE); Peter Lechner, Vaterstetten (DE)

Correspondence Address: FLYNN THIEL BOUTELL & TANIS, P.C., 2026 RAMBLING ROAD, KALAMAZOO, MI, 49008-1631, US

(21) Appl. No.: 12/802,556

(22) Filed: Jun. 9, 2010

(30) Foreign Application Priority Data
Jun. 16, 2009 (DE) 10 2009 025 428.5

(51) Int. Cl. H01L 31/00; H01L 31/18

(52) U.S. Cl. 136/255; 136/252; 136/265; 438/72; 438/98; 257/E31.119; 257/E31.126

(57) ABSTRACT

The present invention relates to a thin-film solar cell and a process for producing it, where the rear-side layer structure of the thin-film solar cell has a multilayer structure comprising a metallic bonding layer, a transition layer and an Ag-containing reflector layer and displays a high degree of reflection and good adhesion of the layer system.

The present invention relates to a thin-film solar cell according to the preamble of the main claim and also a process for producing a thin-film solar cell.

Thin-film solar cells generally comprise a transparent substrate on which a layer sequence comprising a transparent front electrode layer, a photovoltaically active layer system which is generally composed of one or more semiconductor layers, a transparent, conductive barrier layer and a metallic back electrode layer which simultaneously represents the reflector layer and has the task of reflecting incident radiation which has not been absorbed in the first pass through the photovoltaically active layer system back into the semiconductor layers is deposited. Thin-film solar cells are frequently connected in series sectionwise, which can be effected, for example, by introducing lines of separation into the layer system and sectionwise electrical connection of front electrode and back electrode. The subsequent contacting and encapsulation of the thin-film solar cells, e.g. by means of an embedding film and a final glass plate, finally gives a photovoltaic module.

The rear-side layer structure of a thin-film solar cell, which adjoins the photovoltaically active layer system, generally comprises an oxidic barrier layer which has a high transparency and an electrical conductivity and a metallic reflector layer which simultaneously represents the back contact of the thin-film solar cell. Further layers which protect the reflector against environmental influences, e.g. moisture, or else improve solderability can follow. The oxidic barrier layer has, inter alia, the function of a diffusion barrier and prevents metal atoms from the back electrode layer from diffusing or migrating into the silicon layer, which would lead to a great decrease in the efficiency of the solar cell.

A metal film which reflects well in the visible spectral region (VIS) and near infrared spectral region (NIR) is frequently used for the metallic reflector layer. The reflection in the NIR to a wavelength of about 1100 nm is of particular importance here since, owing to the absorption behaviour of the semiconducting layers, this radiation which can be photovoltaically utilized by the component in particular reaches the reflector while radiation having a wavelength below about 700 nm is largely absorbed during the first pass through the semiconducting layers. The metal Al is relatively well-suited as reflector material, but Ag and also Au are in principle even more suitable because of higher reflection capability in the near infrared region. The thickness of the metal reflector layer is generally from 100 to 500 nm. Au is generally ruled out as reflector layer for cost reasons. An Al layer is associated with lower costs but Al has only a moderate degree of reflection in the particularly relevant NIR.

Although Ag has a high degree of reflection at reasonable costs, in contrast to an Al layer an Ag layer generally has only poor adhesion to the oxidic barrier layer. Poor adhesion of the reflector layer, however, leads to a risk to the long-term reliability of the photovoltaic module. Particularly after intrusion of moisture, the reflector layer can delaminate from the intermediate layer and thus lead to failure of the function of the photovoltaic module. Likewise, tearing-off of the layer can occur after contacting of the back electrode by soldering on contact connectors or formation of metal flakes can occur on introduction of the lines of separation for connection in series and these metal flakes can lead to short circuits between the regions connected in series. The use of an Ag reflector directly on the transparent, conductive barrier layer is therefore not advisable.

To improve the adhesion of the silver reflector layer, a thin metallic bonding layer, e.g. of Ti, Cr, Ni or Mo, is, according to the prior art, therefore additionally used between the Ag layer and the transparent, conductive barrier layer. However, this bonding layer generally leads to a significant worsening of the degree of reflection of the reflector, in particular due to the newly generated interfaces between oxidic barrier layer and bonding layer and between bonding layer and reflector layer, but also due to absorption. The decrease in the degree of reflection of the reflector caused by the metallic bonding layer is, averaged over the solar spectrum, about 2-5%.

It is therefore an object of the invention to provide a rear-side layer system based on an Ag reflector for a thin-film solar cell, which displays not only very good reflection properties, in particular in the NIR, based on the Ag reflector but also a sufficiently high adhesion of the layer system, and also a process for producing a thin-film solar cell.

The object is achieved by the independent claims. Preferred embodiments are indicated in the dependent claims.

The main claim relates to a thin-film solar cell having a transparent substrate on which there are arranged a transparent front electrode layer, a photovoltaically active layer system, a transparent, conductive barrier layer and a rear-side layer system which represents the rear-side electrode and the reflector and which comprises a metallic bonding layer and an Ag-containing reflector layer.

For the purposes of the present invention, the term thin-film solar cell encompasses various forms of solar cells which generally have a layer thickness of the photovoltaically active layer system of not more than about 10 μm, with the production of the photovoltaically active layer system generally being carried out directly on an advantageously available substrate, thus requiring no wafer. The cells can be, for example, single or multiple stack cells (e.g. tandem or triple junction stack cells) composed of amorphous and/or microcrystalline semiconductor material. The photovoltaically active layer system in which the transformation of optical energy into electric energy occurs can be based on the semiconductor material Si but can also be based on other systems such as CdTe or Cu(In, Ga)(S, Se)₂. The thin-film solar cell can additionally comprise further elements, e.g. for contacting and for rear-side encapsulation.

The transparent substrate can be a plastic substrate, e.g. composed of polycarbonate, but is preferably a glass substrate because of the higher thermal and chemical resistance. The term transparent relates, both in the case of the substrate and in the case of the front and back electrode, to radiation in the VIS and in the NIR to a wavelength of about 1100 nm and means that, based on a typical solar spectrum, a major part of the incident radiation of at least 50% in this spectral region is transmitted. The transparent substrate can have various materials thicknesses and be in the form of a film or plate. The transparent substrate can also have a microstructured surface or have a microstructured, transparent coating, where the microstructuring brings about a deflection in the direction of the incident radiation. The deflection in direction can bring about an increase in the optical path of the incident radiation through the absorber and thus an increase in the efficiency of the solar cell. This microstructured layer can be, for example, a silicon oxynitride, SnO₂ or ZnO layer, where silicon oxynitride can be described by the formula x SiO₂: (1−x) SiO₃N₄, where x=0 . . . 1. The microstructured side is preferably located on the side of the transparent substrate opposite that struck by the light and is, for example, arranged between substrate and transparent front electrode.

The transparent substrate can also have an antireflection coating composed of one or more layers on the side struck by the light so as to reduce reflection of the incident radiation. Furthermore, further layers for increasing the resistance to environmental influences, in particular moisture, can be present.

The adjoining transparent front electrode layer can comprise, for example, a TCO layer composed of SnO₂, ITO or ZnO, with ZnO preferably being doped with Al, Ga or B and SnO₂ and/or ITO preferably being doped with F.

Antireflection layers can also be present within the layer system in order to reduce reflection losses at the interfaces, e.g. between the transparent substrate and the transparent front electrode layer or between the transparent front electrode layer and the semiconducting layer system.

The transparent front electrode layer is generally followed by the photovoltaically active layer system and the rear-side layer system which essentially has the function of the back electrode and the reflector. A protective layer is often additionally present on the rear side of the actual reflector in order to protect the reflector during, in particular, rear-side contacting but also in later operation, in particular against oxidation.

The thin-film solar cell of the invention according to the preamble of the main claim is characterized in that a transition layer whose composition comprises exclusively the components of the metallic bonding layer and the Ag-containing reflector layer is present between the metallic bonding layer and the Ag-containing reflector layer. Compared to a layer system which has a sharply defined interface between metallic bonding layer and Ag-containing reflector layer, the transition layer enables improved adhesion of the Ag-containing reflector layer to be achieved, since the layers do not go over into one another without a transition and the potential weak point of the sharp interface is avoided.

The metallic bonding layer preferably comprises one of the metals Cu, Cr, Fe, Mn, Ni, Ti, V, Zn, Mo, Zr, Nb, W, Ta, Al, Sn or an alloy of these metals or stainless steel. These metals are 3d elements (Cu, Cr, Fe, Mn, Ni, Ti, V, Zn), 4d elements (Mo, Zr, Nb) and 5d elements (W, Ta) from the transition groups of the Periodic Table which have similar electron configurations, and also Al and Sn. Stainless steel having the main constituent Fe and also frequently Cr, Ni likewise consists mainly of 3d elements. These metals and stainless steel have a strong tendency to form oxide layers and thus generally display good adhesion to the transparent, conductive barrier layer and at the same time, in combination with the transition layer, adhere well to the Ag-containing reflector layer.

The metallic bonding layer preferably comprises Cu. Among the metals mentioned, Cu gives good results as regards the improvement in adhesion of the layer system and also displays very good optical properties since it has a high degree of reflection in the particularly relevant near infrared region (NIR) and a Cu layer therefore impairs the degree of reflection of the reflector structure only slightly.

The metallic bonding layer preferably has a thickness in the range from 1 nm to 50 nm. If the layer thickness is lower, it performs the function of improved layer adhesion to only a limited extent. If the layer thickness is made larger, increasing reflection losses occur. Finally, at layer thicknesses of significantly above 50 nm, the metallic bonding layer also takes over the reflector function since the incident radiation then no longer reaches the Ag-containing reflector layer, albeit at a lower degree of reflection. The advantages of the highly reflective Ag-containing reflector layer can then no longer be realized. Particular preference is therefore given to a thickness of the metallic bonding layer in the range from 2 nm to 20 nm, in which range good adhesion properties and good optical properties are simultaneously achieved.

The Ag-containing reflector layer comprises Ag. It can also consist of an Ag-containing alloy or preferably of pure Ag. The good reflection behaviour displayed by Ag both in the VIS and in the IR is important. Preference is given to using a pure Ag layer.

The Ag-containing reflector layer preferably has a thickness of from 50 nm to 500 nm. The degree of reflection of the Ag-containing reflector layer for visible radiation and NIR (near infrared) increases significantly with increasing layer thickness in the layer thickness range below about 150 nm; in the layer thickness range around 200 nm, only slight increases in the degree of reflection are achieved. Significantly greater layer thicknesses result in only very slight increases in reflection and are therefore no longer economical.

The transition layer preferably has a layer composition which changes perpendicularly to this layer, with the composition of the transition layer at the transition to the adjoining layers in each case approaching the composition of these layers. The transition layer thus effects a particularly soft transition between the metallic bonding layer and the Ag-containing reflector layer.

The transition layer according to the invention has a thickness in the range from 0.1 nm to 20 nm, preferably from 0.5 nm to 10 nm and particularly preferably from 2 nm to 10 nm. The transition layer effects a soft transition between the metallic bonding layer and the Ag-containing reflector layer.

The transparent, conductive barrier layer preferably comprises a transparent conductive oxide (TCO), with the layer thickness being in the range from 10 nm to 300 nm. The conductive barrier layer has, inter alia, the function of preventing diffusion of metallic ions into the photovoltaically active layer system. However, it also acts as bonding layer since most of the layers suitable as reflector display only poor adhesion to the semiconducting material of the photovoltaically active layer system. A minimum thickness of the TCO layer of about 10 nm is necessary for a reliable barrier action. However, the layer thickness should not be too great since the absorption of light radiation in the TCO layer and also the losses in current conduction increase with increasing thickness of the TCO material. The TCO layer also has the action of an interference layer. Optimal total transmission for the relevant solar spectrum is achieved at a layer thickness of about 80 nm. The conductive barrier layer preferably comprises the oxides SnO₂, ITO (indium-tin oxide) or ZnO. The conductive barrier layer can also be doped, with ZnO preferably being doped with Al, Ga or B and SnO₂ and/or ITO preferably being doped with F.

In a preferred embodiment, the Ag-containing reflector layer is provided on its side facing away from the transition layer with a protective layer. This protective layer can be, for example, a layer composed of an NiV alloy. It protects the metallic reflector firstly during the contacting process by soldering and secondly against oxidation which could have an adverse effect on the optical properties of the reflector.

The invention likewise provides a process for producing a thin-film solar cell, which can be used inter alia but not exclusively for producing a thin-film solar cell having the features of the preceding description. The structural constituents of the thin-film solar cell indicated in the description of the thin-film solar cell of the invention and their preferred embodiments therefore also apply to the terms used in the description of the process. This applies, inter alia, to the transparent substrate, the transparent, conductive front electrode layer, the photovoltaically active layer system and the transparent, conductive barrier layer.

The production of the thin-film solar cell up to the deposition of the rear-side layer system can be carried out according to the prior art. In general, the transparent, conductive front electrode layer is firstly deposited on the transparent substrate. This application can, for example, be carried out in a vacuum sputtering process. The photovoltaically active layer system which generally consists of a plurality of semiconductor layers which have different doping is subsequently applied. The coating process used for thin-film silicon solar cells is generally the PECVD (plasma enhanced chemical vapour deposition) process; semiconducting layers of the CdTe type can also be deposited by means of physical sputtering processes. The transparent, conductive barrier layer is then generally deposited. Furthermore, the production process can, before deposition of the rear-side layer system, comprise further processes such as coating processes for applying antireflection layers, bonding layers or microstructured layers and also structuring processes for dividing the thin-film solar cell into a plurality of regions which are finally connected in series by application of the rear-side layer system.

These process steps generally give an intermediate which will hereinafter be referred to as precoated substrate and comprises at least the transparent substrate, the transparent front electrode layer, the photovoltaically active layer system and the transparent, conductive barrier layer. The precoated substrate is generally in the form of a relatively large glass plate having an area of from about 0.1 to 6 m² and a flat surface and the layer system mentioned. Coating of the substrate with the metallic bonding layer, the transition layer and the Ag-containing reflector layer is carried out by means of two coating processes P1 and P2 which are arranged relative to one another so that they have a common coating plane in which the surface to be coated of a substrate is preferably located during coating. The term coating plane is not to be interpreted in the sense of a mathematical plane with zero dimension in the direction of the normal to the area. Rather, the coating plane is the level at which the surfaces of the precoated substrates are approximately positioned during the coating process. Mechanical tolerances in the transport device and also small deviations from planarity of the precoated substrate generally lead to the surface of the precoated substrate not being exactly planar.

In the production process of the invention, the metallic bonding layer is deposited on the precoated substrate in the coating process P1 having a planar coating region B1 in the coating plane in a coating period T1 and the Ag-containing reflector layer is deposited in a second coating process P2 having a planar coating region B2 in the coating plane in a coating period T2, with the production process of the invention being characterized in that the coating periods T1 and T2 at least partly overlap in time and the coating regions B1 and B2 of the coating processes at least partly overlap in a region B3. The two coating processes P1 and P2 are arranged so that they have a common coating plane in which the surface of the precoated substrate is essentially located during coating. In this coating plane, a planar, level coating region B1 or B2 in which a layer is deposited by the respective coating process can be assigned to each coating process. The coating rate will generally not be constant within these coating regions; in general, the coating rate decreases at the margins. The overlap of the two coating regions represents the region B3 which can be coated simultaneously or else offset in time by the two coating processes.

In a preferred embodiment of the process, a transition layer is formed between the metallic bonding layer and the Ag-containing reflector layer. The transition layer is formed by the overlap according to the invention between the coating regions and also the overlap in time between the coating periods. This means, in particular, that the transition layer is not assigned its own coating process but the transition layer is produced concomitantly by the coating processes P1 and P2 in the region B3. A separate coating process for producing a transition layer would also be possible, but this would be associated with a significantly higher outlay and is therefore not a preferred embodiment.

The process of the invention is suitable for producing transition layers having the preferred features described in respect of the thin-film solar cell, and these features are likewise claimed for the process. These include the thicknesses and compositions of the transition layer and also, in particular, the fact that the transition layer preferably has a composition which changes perpendicularly to the layer, with the composition of the transition layer at the transition to the adjoining layers in each case approaching the composition of these layers.

In a preferred embodiment of the process, the precoated substrate is conveyed in a transport direction so that its surface passes through the coating regions B1 and B2 of the coating processes and also the region B3 in which the two regions B1 and B2 overlap, with the precoated substrate preferably being conveyed at a constant speed. The coating processes are preferably arranged so that the coating regions B1 and B2 are arranged behind one another in the transport direction in the coating plane and the overlap region B3 has an area corresponding to from 1 to 60% of the area of the coating region B1. The constant speed makes a steady-state process with optimal efficiency possible.

In a further preferred embodiment of the process, the coating processes P1 and P2 are constantly in operation during coating of a precoated substrate and the overall process is essentially steady-state. The steady-state operation of the process has numerous advantages compared to carrying out the coating processes P1 and P2 sequentially with a change over time of the deposition rate of the coating processes. In constant operation of the coating processes, an equilibrium state with, for example, constant temperature of the sputtering target is established, so that a constant ablation rate is achieved. The steady-state operation of the process therefore has a positive effect on the stability and controllability of the overall process, on the quality of the thin-film solar cells and, in particular, on the throughput, since no pauses in coating operation caused by the process occur. The precoated substrates are normally in the form of plates having a finite length, as a result of which the overall process is strictly speaking not steady-state but has a periodic character. However, this discontinuity plays no role in the operation of the overall process, so that the process can in this sense be considered to be essentially steady-state.

In a preferred embodiment of the process, the coating regions B1 and B2 lying in the coating plane each have an elongated, rounded geometry and the dimension of these coating regions B1 and B2 perpendicular to the transport direction corresponds essentially to the dimension of the precoated substrate perpendicular to the transport direction. The coating regions B1 and B2 can slightly exceed the dimension of the precoated substrate perpendicular to the transport direction, which can aid attainment of a uniformly constant layer thickness from the middle to the margin of the substrate to be coated. A corresponding design of the coating region is generally necessary since the coating rate is in many coating processes not constant over the entire coating region but decreases towards the edges of the coating region.

In a preferred embodiment of the process, the region B3 likewise has an elongated, rounded geometry and the dimension of this region B3 perpendicular to the transport direction corresponds essentially to the dimension of the precoated substrate perpendicular to the transport direction.

In a preferred embodiment of the process, the coating processes P1 and P2 are carried out within a process chamber which can be evacuated. Vacuum coating processes are particularly suitable for the deposition of the metallic layers; in particular, oxidation is avoided by means of an atmosphere which is low in oxygen.

In a preferred embodiment of the process, one or both of the coating processes P1 and P2 is a PVD (physical vapour deposition) process, preferably magnetron sputtering. Large-area coatings which are low in impurities and have a uniform thickness can be produced particularly well by this coating process. A tubular cathode rotating about its longitudinal axis is preferably used as sputtering target. Interfering effects such as, in particular, a nonuniform layer thickness in the marginal region of the coating can in this way be significantly reduced compared to planar targets.

In a preferred embodiment of the process, a noble gas or a noble gas mixture is used as a sputtering gas.

In a further possible embodiment of the process, the coating regions B1 and B2 essentially correspond, with the rear-side layer system of the invention then being able to be produced by carrying out the coating processes P1 and P2 offset in time with an overlapping time of the coating periods T1 and T2. In this case, the precoated substrate is preferably not subject to any movement relative to the coating regions, i.e. is fixed in place. However, this embodiment of the production process is not preferred since the process is not steady-state and also does not have an optimal throughput.

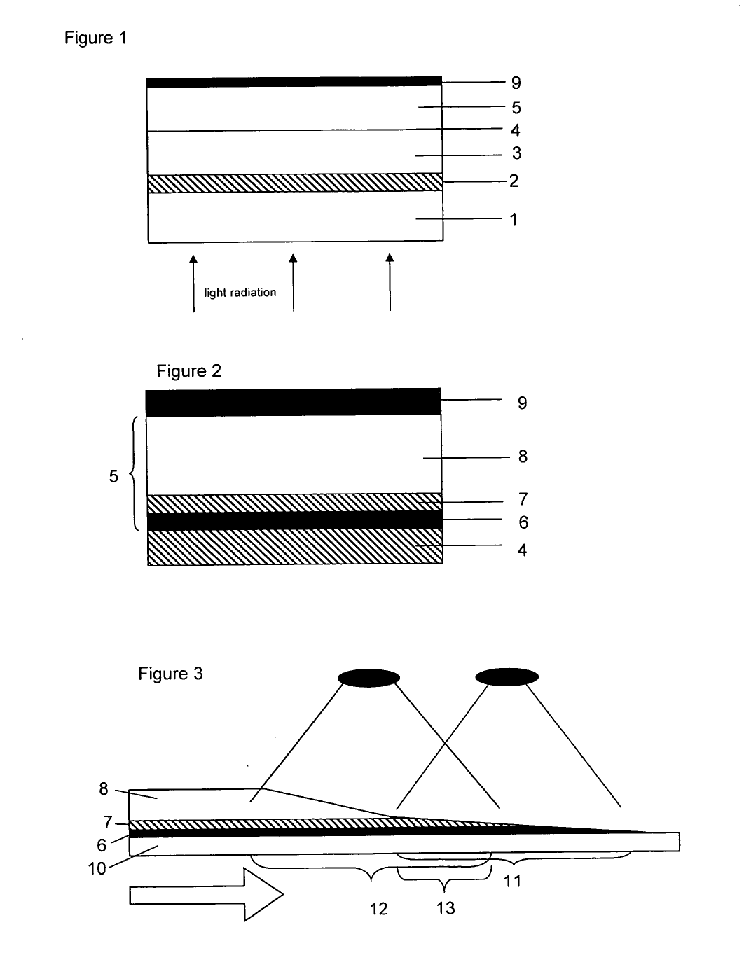

The thin-film solar cell of the invention and the production process of the invention are illustrated below in FIGS. 1 to 3.

In the figures:

FIG. 1 schematically shows the layer system of a thin-film solar cell according to the prior art

FIG. 2 schematically shows the rear-side layer system of a thin-film solar cell according to the invention with adjoining layers

FIG. 3 schematically shows the steady-state embodiment of the production process with the simultaneous coating processes P1 and P2 and with movement of the precoated substrate

The layer thicknesses are not shown true to scale in the figures. In addition, further layers which are not of direct importance for the description of the invention and are therefore not shown can also be present in the structure. Likewise, a detailed depiction of the substructure of the photovoltaically active layer system (3) and of the precoated substrate (10) have been omitted in FIG. 3.

FIG. 1 schematically shows the structure of a thin-film solar cell according to the prior art, where the transparent, conductive front electrode layer (2), the photovoltaically active layer system (3), the transparent conductive barrier layer (4) and the rear-side layer system (5), which according to the prior art generally comprises only a metallic reflector layer, e.g. a layer of Al, which simultaneously represents the back electrode, and a protective layer (9) are arranged on a transparent substrate (1).

FIG. 2 schematically shows the structure of the rear-side layer system (5) of a thin-film solar cell according to the invention with the adjoining layers, where the rear-side layer system (5) comprises the metallic bonding layer (6), the transition layer (7), the Ag-containing reflector layer (8) and a protective layer (9).

FIG. 3 schematically shows a preferred steady-state embodiment of the production process for the thin-film solar cell of the invention or for the rear-side layer system according to the invention with the simultaneous coating processes P1 and P2, where the precoated substrate which already comprises the transparent, conductive front electrode layer (2), the photovoltaically active layer system (3) and the transparent conductive barrier layer (4) passes through the coating regions B1 (11), B3 (13) and the coating region B2 (12), preferably in a vacuum chamber and preferably at constant speed. Each place on the precoated substrate is thus firstly coated with the metallic bonding layer (6), the transition layer (7) and the Ag-containing reflector layer (8).

The advantageous properties of the invention are illustrated with the aid of the following example:

| | |
|---|---|
| Transparent substrate: | substrate glass |
| Transparent front electrode layer: | F-doped SnO₂ |
| PV-active layer system: | type a-Si, pin-pin structure |
| Transparent conductive barrier layer: | ZnO, 80 nm |
| Metallic bonding layer | Cu, layer thickness about 7 nm |
| Transition layer | Cu—Ag, layer thickness |
| | about 0.5 nm |
| Ag-containing reflector layer | Ag, layer thickness 190 nm |
| Protective layer | NiV, layer thickness |
| | about 75 nm |

To produce this layer system, the photovoltaically active a-Si layer system (amorphous Si) having a pin-pin structure was deposited by means of PECVD onto the transparent substrate glass which already had a transparent front electrode layer, and an about 80 nm thick ZnO layer which represents the transparent conductive barrier layer was subsequently deposited. The deposition of the rear-side layer system according to the invention was carried out in the pressure range from 1×10⁻⁴ mbar to 1×10⁻³ mbar in a vacuum process chamber through which the precoated substrate was conveyed at constant speed on rollers during the coating process. Along the transport path, the precoated substrate passed through the coating regions of two magnetron sputtering processes which each have a tubular sputtering target (tubular cathodes). The tubular cathodes of the two sputtering processes, whose longitudinal axes are aligned parallel to one another and perpendicular to the transport direction, were located at a distance of about 80 mm from the coating plane and had a spacing between them of about 190 nm, so that there is spatial overlap between the two coating regions. The energy density on the tubular sputtering target, which is a measure of the ablation rate of the sputtering target and thus of the coating rate, was about 1 W/cm² in the first sputtering process for producing the Cu layer, about 10 W/cm² in the second sputtering process for producing the Ag layer, resulting in the different thicknesses of the Cu and Ag layers. In the first sputtering process, a Cu layer having a thickness of about 7 nm was deposited, while an Ag layer having a thickness of about 190 nm was deposited in the second sputtering process, with the transition layer being produced between the Cu layer and the Ag layer. Furthermore, the Ag layer was provided with an about 75 nm thick NiV layer.

To demonstrate the properties according to the invention, thin-film solar cells were produced for comparison by a method analogous to the production process described but with the Cu layer and the Ag layer being deposited separately so that no transition layer is produced. For this purpose, only the Cu layer was deposited on the precoated substrate in a first step and the Ag layer was subsequently deposited in a second step without an overlap in time.

To determine the adhesive strength, metal tapes having a width of about 5 mm were soldered onto the protective layer and a tensile force was applied perpendicularly to the layer structure via these metal tapes. The tensile force was slowly increased until the metal tape together with part of the layer system in the form of a strip became detached from the substrate. Here, the critical tensile force at which detachment of the layers commences was determined. On the basis of experience, the pull-off force in this test should have a minimum value of about 4 N. In the case of the thin-film solar cells produced according to the invention, 94.2% achieved a satisfactory value of the pull-off force of at least 4 N. In the case of the comparative specimens without a transition layer, only 92.5% achieved a satisfactory value of the pull-off force of at least 4 N.

The reflection properties of the rear-side layer system according to the invention were determined by means of a reflection spectrometer. To be able to determine the optical influence of the rear-side layer system as accurately as possible, special specimens in which the back contact (ZnO, Cu, Cu—Ag intermediate layer, Ag, NiV) had been deposited on a glass substrate or, to achieve better optical matching of the back reflector to the silicon, on a glass substrate onto which a 30 nm thick layer of amorphous silicon had been deposited were produced.

The optical measurements demonstrated, firstly, that a Cu layer having a thickness of about 6 nm deposited separately before the Ag layer leads to only a very slight decrease in the spectral degree of reflection of the Ag reflector having a Cu bonding layer compared to a reflector without a Cu bonding layer. The Cu leads to a significant decrease in the reflection of more than 1% only in the nonrelevant spectral regions below 600 nm and above 1100 nm, while no significant decrease in the reflection of more than 1% was found in the relevant spectral region from about 700 nm to 1100 nm.

Furthermore, optical measurements demonstrated that the spectral degree of reflection of the reflector according to the invention having a transition layer likewise does not differ significantly from that of a reflector (Cu-transition layer-Ag) without transition layer in the spectral region from 700 nm to 1100 nm.

The spectral degree of reflection of the reflector according to the invention thus corresponds within measurement accuracy (<1%) in the relevant spectral region to that of a pure Ag reflector without transition layer, which cannot be used because of the adhesion problems.

In summary, it can be said that in the spectral region from 700 nm to 1100 nm the thin-film solar cell of the invention has the advantages of the high degree of reflection of an Ag-containing reflector and at the same time displays good adhesion of the total layer system, in particular of the Ag reflector. The good adhesion is achieved in a particularly advantageous way by means of a very thin metallic bonding layer and a transition layer between the metallic layer and the Ag-containing reflector layer, which transition layer is deposited in a simultaneous coating process for the Ag-containing reflector layer and the metallic bonding layer and whose production therefore does not require an additional process step.

As metallic bonding layer, Cu in particular has been found to be outstandingly suitable because of its good reflection properties in the relevant spectral region. The rear-side layer system according to the invention has excellent reflection properties and also very good adhesion properties.

1. Thin-film solar cell having a transparent substrate (1) on which there are arranged a transparent front electrode layer (2), a photovoltaically active layer system (3), a transparent, conductive barrier layer (4) and a rear-side layer system (5) comprising a metallic bonding layer (6) and an Ag-containing reflector layer (8), characterized in that a transition layer (7) whose composition comprises exclusively components of the metallic bonding layer (6) and the Ag-containing reflector layer (8) is present between the metallic bonding layer (6) and the Ag-containing reflector layer (8).

2. Thin-film solar cell according to claim 1, wherein the metallic bonding layer (6) comprises one of the metals Cu, Cr, Fe, Mn, Ni, Ti, V, An, Mo, Zr, Nb, W, Ta, Al, Sn or an alloy of these metals or stainless steel.

3. Thin-film solar cell according to claim 1, wherein the metallic bonding layer (6) consists essentially of Cu.

4. Thin-film solar cell according to claim 1, wherein the metallic bonding layer (6) has a thickness in the range from 1 nm to 50 nm, preferably from 2 nm to 20 nm.

5. Thin-film solar cell according to claim 1, wherein the Ag-containing reflector layer (8) comprises Ag or consists of an Ag-containing alloy or preferably of pure Ag.

6. Thin-film solar cell according to claim 1, wherein the Ag-containing reflector layer (8) has a thickness in the range from 50 nm to 500 nm.

7. Thin-film solar cell according to claim 1, wherein the transition layer (7) has a composition which changes perpendicularly to this layer, with the composition of the transition layer (7) at the transition to the adjoining layers (6) and (8) in each case approaching the composition of these layers.

8. Thin-film solar cell according to claim 1, wherein the thickness of the transition layer is in the range from 0.1 nm to 20 nm, preferably from 0.5 nm to 10 nm and particularly preferably from 2 nm to 10 nm.

9. Thin-film solar cell according to claim 1, wherein the transparent, conductive barrier layer (4) comprises a transparent conductive oxide (TCO) and its thickness is in the range from 10 nm to 300 nm.

10. Thin-film solar cell according to claim 1, wherein the transparent, conductive barrier layer (4) comprises SnO₂, ITO (indium-tin oxide) or ZnO.

11. Thin-film solar cell according to claim 1, wherein the transparent, conductive barrier layer (4) is doped, with ZnO preferably being doped with Al or Ga or B and SnO₂ and/or ITO preferably being doped with F.

12. Thin-film solar cell according to claim 1, wherein the Ag-containing reflector layer (8) is provided on its side facing away from the transition layer (7) with a protective layer (9).

13. Process for producing a thin-film solar cell, wherein a metallic bonding layer (6) is deposited on a precoated substrate (10) comprising at least one transparent substrate (1), a transparent front electrode layer, a photovoltaically active layer system (3) and a transparent, conductive barrier layer (4) in a coating process P1 having a planar coating region B1 (11) in a coating plane in a coating period T1 and an Ag-containing reflector layer (8) is deposited in a second coating process P2 having a planar coating region B2 (12) in the coating plane in a coating period T2, characterized in that the coating periods T1 and T2 at least partly overlap in time and the coating regions B1 (11) and B2 (12) of the coating processes at least partly overlap in a region B3 (13) in the coating plane.

14. Process according to claim 13, wherein a transition layer (7) is formed between the metallic bonding layer (6) and the Ag-containing reflector layer (8).

15. Process according to claim 13, wherein the metallic bonding layer (6) comprises one of the metals Cu, Cr, Fe, Mn, Ni, Ti, V, Zn, Mo, Zr, Nb, W, Ta, Al, Sn or an alloy of these metals or stainless steel.

16. Process according to claim 13, wherein the metallic bonding layer (6) consists essentially of Cu.

17. Process according to claim 13, wherein the metallic bonding layer (6) has a thickness in the range from 1 nm to 50 nm, preferably from 2 nm to 20 nm.

18. Process according to claim 13, wherein the Ag-containing reflector layer (8) comprises Ag or consists of an Ag-containing alloy or preferably of pure Ag.

19. Process according to claim 13, wherein the Ag-containing reflector layer (8) has a thickness in the range from 50 nm to 500 nm.

20. Process according to claim 14, wherein the transition layer (7) has a composition which changes perpendicularly to this layer, with the composition of the transition layer (7) at the transition to the adjoining layers (6) and (8) in each case approaching the composition of these layers.

21. Process according to claim 14, wherein the thickness of the transition layer is in the range from 0.1 nm to 20 nm, preferably from 0.5 nm to 10 nm and particularly preferably from 2 nm to 10 nm.

22. Process according to claim 13, wherein the precoated substrate (10) is conveyed in a transport direction so that its surface runs through the coating regions B1 (11) and B2 (12) of the coating processes and also the region B3 (13) in which the two regions B1 (11) and B2 (12) overlap, with the precoated substrate (10) preferably being conveyed at a constant speed.

23. Process according to claim 13, wherein the coating processes P1 and P2 are constantly in operation during coating of the precoated substrate (10) and the total process is essentially steady-state.

24. Process according to claim 13, wherein the coating regions B1 (11) and B2 (12) located in the coating plane each have an elongated, rounded geometry and the dimension of these coating regions B1 (11) and B2 (12) perpendicular to the transport direction corresponds essentially to the dimension of the precoated substrate (10) perpendicular to the transport direction.

25. Process according to claim 13, wherein the region B3 (13) likewise has an elongated, rounded geometry and the dimension of this region B3 (13) perpendicular to the transport direction corresponds essentially to the dimension of the precoated substrate (10) perpendicular to the transport direction.

26. Process according to claim 13, wherein the coating processes P1 and P2 are carried out within a process chamber which can be evacuated.

27. Process according to claim 13, wherein one or both coating processes (P1 and P2) are a PVD (physical vapour deposition) process, preferably magnetron sputtering.

28. Process according to claim 13, wherein a noble gas or a noble gas mixture is used as sputtering gas.

29. Process according to claim 14, wherein the coating regions B1 (11) and B2 (12) essentially correspond and the metallic bonding layer (6), the intermediate layer (7) and the Ag-containing reflector layer (8) are produced by a sequence in time of the coating processes P1 and P2 with an overlap in time.
